(19) United States
(12) Patent Application Publication
(10) Pub. No.: US 2024/0153866 A1
(43) Pub. Date: May 9, 2024

(54) INTERCONNECT WITH METAL VIA STRUCTURES

(71) Applicant: International Business Machines Corporation, Armonk, NY (US)

(72) Inventors: Lawrence A. Clevenger, Saratoga Springs, NY (US); Brent A. Anderson, Jericho, VT (US); Albert M. Chu, Nashua, NH (US); Nicholas Anthony Lanzillo, Wynantskill, NY (US); Reinaldo Vega, Mahopac, NY (US); Ruilong Xie, Niskayuna, NY (US)

(21) Appl. No.: 17/981,828

(22) Filed: Nov. 7, 2022

(51) Int. Cl. H01L 23/522; H01L 23/532

(52) U.S. Cl. CPC H01L 23/5226; H01L 23/53214; H01L 23/53257

(57) ABSTRACT

An interconnect structure includes a first metallization layer, a second metallization layer, and a via metallization layer connecting the first metallization layer to the second metallization layer. The via metallization layer includes a metal via having a first portion extending in a first direction and a second portion extending from the first portion in a second direction different than the first direction.

### BACKGROUND

Generally, semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. Within an interconnect structure, conductive vias can run perpendicular to the substrate and conductive lines can run parallel to the substrate.

### SUMMARY

Illustrative embodiments of the present application include techniques for use in semiconductor manufacture. In an illustrative embodiment, an interconnect structure comprises a first metallization layer, a second metallization layer, and a via metallization layer connecting the first metallization layer to the second metallization layer. The via metallization layer comprises a metal via having a first portion extending in a first direction and a second portion extending from the first portion in a second direction different than the first direction.

According to another exemplary embodiment, an interconnect structure comprises a first metallization layer, a second metallization layer; and a via metallization layer connecting the first metallization layer to the second metallization layer. The via metallization layer comprises a metal via having a first portion extending in a first direction and a second portion extending from the first portion in a second direction different than the first direction. The first portion of the metal via has a first width and the second via portion of the metal via has a second width different than the first width.

According to yet another exemplary embodiment, an integrated circuit comprises one or more semiconductor structures. At least one of the one or more semiconductor structures comprises an interconnect structure comprising a first metallization layer, a second metallization layer, and a via metallization layer connecting the first metallization layer to the second metallization layer. The via metallization layer comprises a metal via having a first portion extending in a first direction and a second portion extending from the first portion in a second direction different than the first direction.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a top view of a semiconductor structure at a first-intermediate fabrication stage, according to an illustrative embodiment.

FIG. 1B depicts a side cross-sectional view of the semiconductor structure taken along the X-X axis of FIG. 1A for use at the first-intermediate fabrication stage, according to an illustrative embodiment.

FIG. 1C depicts a side cross-sectional view of the semiconductor structure taken along the Y1-Y1 axis of FIG. 1A for use at the first-intermediate fabrication stage, according to an illustrative embodiment.

FIG. 1D depicts a side cross-sectional view of the semiconductor structure taken along the Y2-Y2 axis of FIG. 1A for use at the first-intermediate fabrication stage, according to an illustrative embodiment.

FIG. 2A is a top view of a semiconductor structure at a second-intermediate fabrication stage, according to an illustrative embodiment.

FIG. 2B depicts a side cross-sectional view of the semiconductor structure taken along the X-X axis of FIG. 2A for use at the second-intermediate fabrication stage, according to an illustrative embodiment.

FIG. 2C depicts a side cross-sectional view of the semiconductor structure taken along the Y1-Y1 axis of FIG. 2A for use at the second-intermediate fabrication stage, according to an illustrative embodiment.

FIG. 2D depicts a side cross-sectional view of the semiconductor structure taken along the Y2-Y2 axis of FIG. 2A for use at the second-intermediate fabrication stage, according to an illustrative embodiment.

FIG. 3A is a top view of a semiconductor structure at a third-intermediate fabrication stage, according to an illustrative embodiment.

FIG. 3B depicts a side cross-sectional view of the semiconductor structure taken along the X-X axis of FIG. 3A for use at the third-intermediate fabrication stage, according to an illustrative embodiment.

FIG. 3C depicts a side cross-sectional view of the semiconductor structure taken along the Y1-Y1 axis of FIG. 3A for use at the third-intermediate fabrication stage, according to an illustrative embodiment.

FIG. 3D depicts a side cross-sectional view of the semiconductor structure taken along the Y2-Y2 axis of FIG. 3A for use at the third-intermediate fabrication stage, according to an illustrative embodiment.

FIG. 4A is a top view of a semiconductor structure at a fourth-intermediate fabrication stage, according to an illustrative embodiment.

FIG. 4B depicts a side cross-sectional view of the semiconductor structure taken along the X-X axis of FIG. 4A for use at the fourth-intermediate fabrication stage, according to an illustrative embodiment.

FIG. 4C depicts a side cross-sectional view of the semiconductor structure taken along the Y1-Y1 axis of FIG. 4A for use at the fourth-intermediate fabrication stage, according to an illustrative embodiment.

FIG. 4D depicts a side cross-sectional view of the semiconductor structure taken along the Y2-Y2 axis of FIG. 4A for use at the fourth-intermediate fabrication stage, according to an illustrative embodiment.

FIG. 5A is a top view of a semiconductor structure at a fifth-intermediate fabrication stage, according to an illustrative embodiment.

FIG. 5B depicts a side cross-sectional view of the semiconductor structure taken along the X-X axis of FIG. 5A for use at the fifth-intermediate fabrication stage, according to an illustrative embodiment.

FIG. 5C depicts a side cross-sectional view of the semiconductor structure taken along the Y1-Y1 axis of FIG. 5A for use at the fifth-intermediate fabrication stage, according to an illustrative embodiment.

FIG. 5D depicts a side cross-sectional view of the semiconductor structure taken along the Y2-Y2 axis of FIG. 5A for use at the fifth-intermediate fabrication stage, according to an illustrative embodiment.

FIG. 6A depicts a side cross-sectional view of the semiconductor structure taken along the X-X axis of FIG. 5A for use at a sixth-intermediate fabrication stage, according to an illustrative embodiment.

FIG. 6B depicts a side cross-sectional view of the semiconductor structure taken along the Y1-Y1 axis of FIG. 5A for use at the sixth-intermediate fabrication stage, according to an illustrative embodiment.

FIG. 6C depicts a side cross-sectional view of the semiconductor structure taken along the Y2-Y2 axis of FIG. 5A for use at the sixth-intermediate fabrication stage, according to an illustrative embodiment.

FIG. 7A is a top view of a semiconductor structure at a seventh-intermediate fabrication stage, according to an illustrative embodiment.

FIG. 7B depicts a side cross-sectional view of the semiconductor structure taken along the X-X axis of FIG. 7A for use at the seventh-intermediate fabrication stage, according to an illustrative embodiment.

FIG. 7C depicts a side cross-sectional view of the semiconductor structure taken along the Y1-Y1 axis of FIG. 7A for use at the seventh-intermediate fabrication stage, according to an illustrative embodiment.

FIG. 7D depicts a side cross-sectional view of the semiconductor structure taken along the Y2-Y2 axis of FIG. 7A for use at the seventh-intermediate fabrication stage, according to an illustrative embodiment.

### DETAILED DESCRIPTION

This disclosure relates generally to semiconductor devices, and more particularly to interconnects having variable via structures between metallization layers and methods for their fabrication. However, it is to be understood that embodiments of the invention are not limited to the illustrative methods, apparatus, systems and devices but instead are more broadly applicable to other suitable methods, apparatus, systems and devices.

A semiconductor device can include multiple metallization layers (“levels”), each including a conductive line (“line”) formed in an interlevel dielectric layer (ILD). Although the term metallization is used herein, metallization layers can be formed to include any suitable conductive material in accordance with the embodiments described herein. Upper lines can be connected to lower lines by vias. Levels can be identified herein using the designation X, where X is a positive integer from 1 to N. The levels are identified from the level closest to the substrate to the level furthest from the substrate as 1 through N where 1 is the first or lowermost level and N is the last or uppermost level. A line in the X level is designated as an Mx line, and a via in the X level is designated as a V_{(X-1}) via. Note that there are no Vo vias or via bars. When a line in an upper level is designated Mx, then a line in an immediately lower level can be designated M_{(X-1)}. Likewise, when a line in a lower level is designated Mx, then a line in an immediately higher level is designated M_{(X-1)}. For a first level (X=1), the line is M₁ and there are no “Vo” vias as the connection from M₁ to devices below M₁ is generally made through separately formed contacts in a contact layer (“CA”). For a second level (X=2), the line is M₂ and the vias are V₁ and, for a third level (X=3), the line is M₃ and the vias or via bars are V₃.

Presently, interconnects are formed having a damascene structure for a metal line and via. The via will typically have a limited size which is undesirable. The illustrative embodiments described herein overcome the foregoing drawbacks by increasing the size of the via structure in the interconnect which in turn significantly increases the via metallization layer resistance.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be used to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, layers, regions, or structures, and thus, a detailed explanation of the same or similar features, elements, layers, regions, or structures will not be repeated for each of the drawings. Also, in the figures, the illustrated scale of one layer, structure, and/or region relative to another layer, structure, and/or region is not necessarily intended to represent actual scale.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

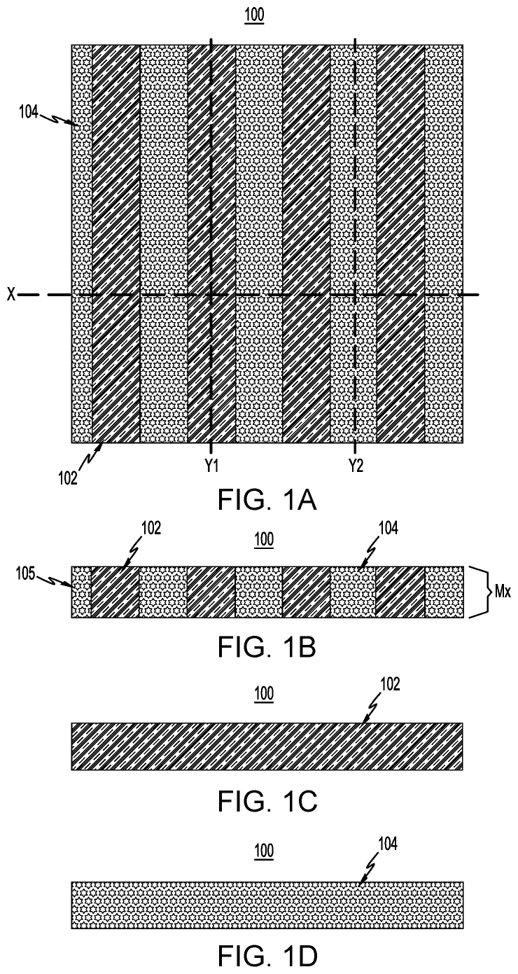

Referring now to the drawings in which like numerals represent the same of similar elements, FIGS. 1A-7D illustrate various processes for fabricating interconnects with variable via structures. Note that the same reference numeral (100) is used to denote the semiconductor structure through the various intermediate fabrication stages illustrated in FIGS. 1A-7D. Note also that the semiconductor structure described herein can also be considered to be a semiconductor device and/or an integrated circuit, or some part thereof. For the purpose of clarity, some fabrication steps leading up to the production of the semiconductor structures as illustrated in FIGS. 1A-7D are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1A shows a top-down view of a semiconductor structure 100, following formation of a first metallization layer having a plurality of metal containing lines 104 disposed in dielectric layer 102. FIG. 1B shows a first side cross-sectional view of semiconductor structure 100, taken along the X-X axis in the top-down view of FIG. 1A. FIG. 1C shows a second side cross-sectional view of semiconductor structure 100, taken along the Y1-Y1 axis in the top-down view of FIG. 1A. FIG. 1D shows a third side cross-sectional view of semiconductor structure 100, taken along the Y2-Y2 axis in the top-down view of FIG. 1A.

Semiconductor structure 100 includes a first metallization layer 105 (also referred to as first metallization layer Mx where x is an integer greater than or equal to 1) having a plurality of metal containing lines 104 disposed in dielectric layer 102. To form the first metallization layer 105, a dielectric layer 102 is typically deposited on a substrate layer (not shown). Dielectric layer 102 may be made of any known dielectric material such as, for example, silicon oxide, silicon nitride, hydrogenated silicon carbon oxide, low-k dielectrics, ultralow-k dielectrics, flowable oxides, porous dielectrics, or organic dielectrics including porous organic dielectrics. Low-k dielectric materials have a nominal dielectric constant less than the dielectric constant of SiO₂, which is approximately 4 (e.g., the dielectric constant for thermally grown silicon dioxide can range from 3.9 to 4.0). In one embodiment, low-k dielectric materials may have a dielectric constant of less than 3.7. Suitable low-k dielectric materials include, for example, fluorinated silicon glass (FSG), carbon doped oxide, a polymer, a SiCOH-containing low-k material, a non-porous low-k material, a porous low-k material, a spin-on dielectric (SOD) low-k material, or any other suitable low-k dielectric material. Ultra-low-k dielectric materials have a nominal dielectric constant less than 2.5. Suitable ultra-low-k dielectric materials include, for example, SiOCH, porous pSiCOH, pSiCNO, carbon rich silicon carbon nitride (C-Rich SiCN), porous silicon carbon nitride (pSiCN), boron and phosporous doped SiCOH/pSiCOH and the like.

The dielectric layer 102 may be formed by any suitable deposition technique known in the art, including atomic layer deposition (ALD), chemical vapor deposition (CVD), plasma enhanced chemical vapor deposition (PECVD), physical vapor deposition (PVD), molecular beam deposition (MBD), pulsed laser deposition (PLD), chemical solution deposition or other like processes. Subsequently, a planarization process such as a standard planarization process (e.g., a chemical mechanical planarization (CMP) process) can be carried out to planarize the upper surface of dielectric layer 102.

The substrate layer (not shown) can include a semiconductor material, which can be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The substrate layer can include a bulk semiconductor substrate or a semiconductor-on-insulator (SOI) substrate. Also, the substrate layer can be at least one semiconductor device such as a field effect transistor, a bipolar transistor, a diode, a resistor, a capacitor, an inductor, an electrically programmable fuse, or any combination thereof.

The metal containing lines 104 may be formed using photolithography, etching and deposition processes. For example, in some embodiments, a pattern (not shown) is produced on dielectric layer 102 by applying a photoresist to the surface to be etched; exposing the photoresist to a pattern of radiation; and then developing the pattern into the photoresist utilizing resist developer. Once the patterning of the photoresist is completed, the photoresist is removed. The etching process may be a subtractive etch, e.g., an anisotropic etch, such as reactive ion etch (RIE). The etch process may also be a selective etch process.

A conductive metal can then be deposited in the openings formed in patterned dielectric layer 102 using any conventional deposition process such as ALD, PVD, CVD or electroplating. A suitable conductive metal includes, for example, aluminum (Al), chromium (Cr), cobalt (Co), hafnium (Hf), iridium (Ir), molybdenum (Mo), niobium (Nb), osmium (Os), rhenium (Re), rhodium (Rh), ruthenium (Ru), tantalum (Ta), titanium (Ti), tungsten (W), vanadium (V), zirconium (Zr), and alloys thereof. In one embodiment, a conductive metal is Ru. Subsequently, a planarization process such as a standard planarization process (e.g., a CMP process) can be carried out to planarize the upper surface of the semiconductor structure 100.

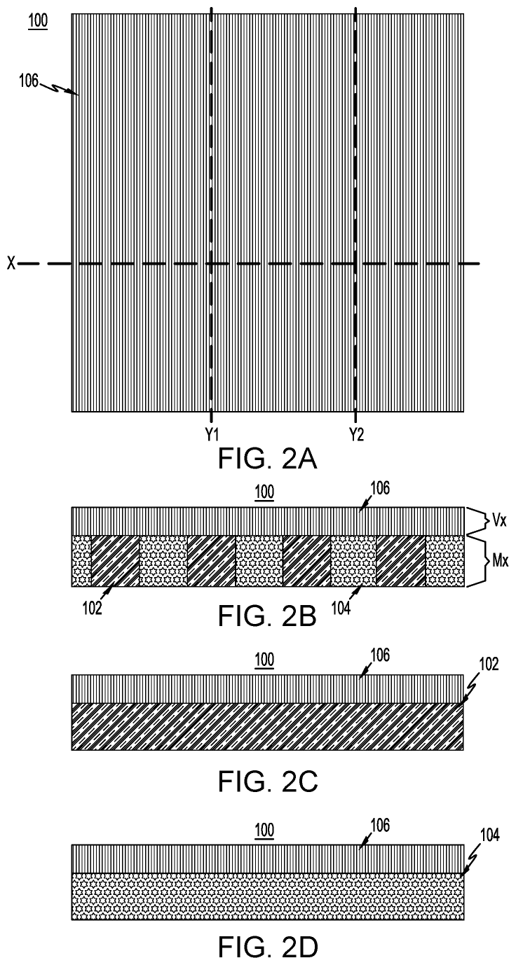

FIG. 2A shows a top-down view of a semiconductor structure 100, following formation of a conductive metal for forming a via metallization layer 106 (also referred to as via metallization layer Vx) on the plurality of metal containing lines 104 and dielectric layer 102 to connect the first metallization layer Mx with a second metallization layer (Mx+1) as discussed below. FIG. 2B shows a first side cross-sectional view of semiconductor structure 100, taken along the X-X axis in the top-down view of FIG. 2A. FIG. 2C shows a second side cross-sectional view of semiconductor structure 100, taken along the Y1-Y1 axis in the top-down view of FIG. 2A. FIG. 2D shows a third side cross-sectional view of semiconductor structure 100, taken along the Y2-Y2 axis in the top-down view of FIG. 2A.

Via metallization layer 106 can be formed by depositing a conductive metal layer on the plurality of metal containing lines 104 and dielectric layer 102 using any conventional deposition process such as ALD, PVD, CVD or electroplating. A suitable conductive metal can be any of the conductive metals discussed above. Subsequently, a planarization process such as a standard planarization process such as a CMP process can be carried out to planarize the upper surface of the semiconductor structure 100.

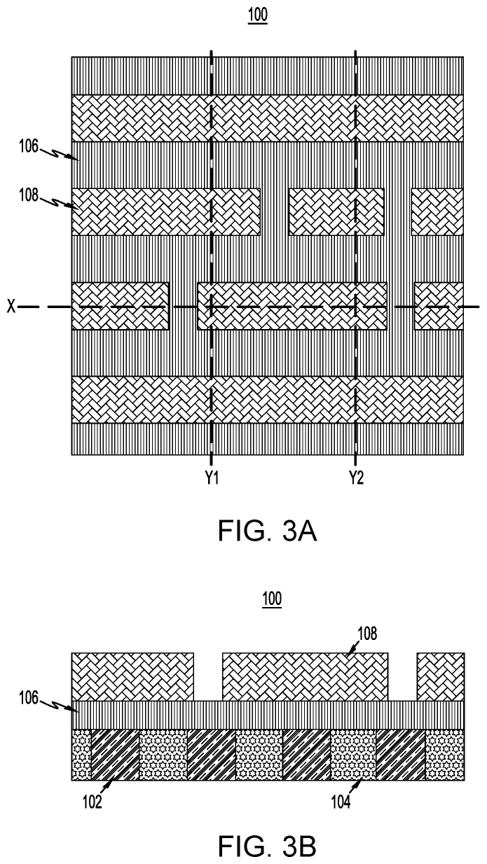

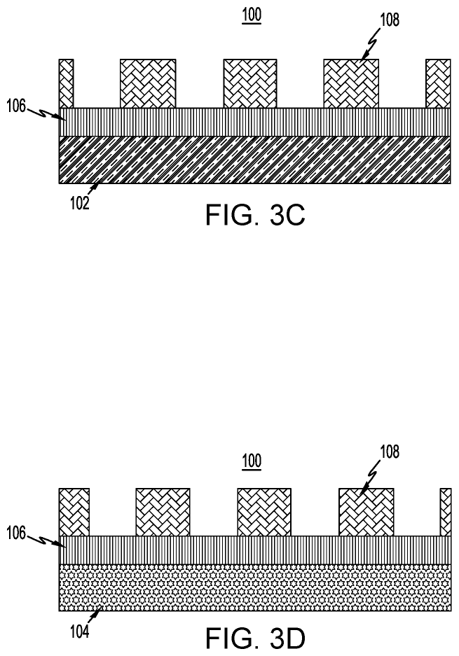

FIG. 3A shows a top-down view of a semiconductor structure 100, following depositing a conductive metal for forming a second metallization layer 108 (also referred to as second metallization layer Mx+1) on the via metallization layer 106. FIG. 3B shows a first side cross-sectional view of semiconductor structure 100, taken along the X-X axis in the top-down view of FIG. 3A. FIG. 3C shows a second side cross-sectional view of semiconductor structure 100, taken along the Y1-Y1 axis in the top-down view of FIG. 3A. FIG. 3D shows a third side cross-sectional view of semiconductor structure 100, taken along the Y2-Y2 axis in the top-down view of FIG. 3A.

A conductive metal is deposited on via metallization layer 106 in a similar manner and of a similar material as discussed above. Next, the conductive metal is patterned and etched using standard photolithography and etching processes. For example, an etching process may be a subtractive etch, e.g., an anisotropic etch, such as RIE, in which the conductive metal is etched until via metallization layer 106 is reached.

In a non-limiting illustrative embodiment, a conductive metal for forming second metallization layer Mx+1 and the conductive metal for forming via metallization layer Vx are different. In a non-limiting illustrative embodiment, a conductive metal for forming second metallization layer Mx+1 is Ru and the conductive metal for forming via metallization layer Vx is Co. In a non-limiting illustrative embodiment, a conductive metal for forming second metallization layer Mx+1 is Ru and the conductive metal for forming via metallization layer Vx is Al.

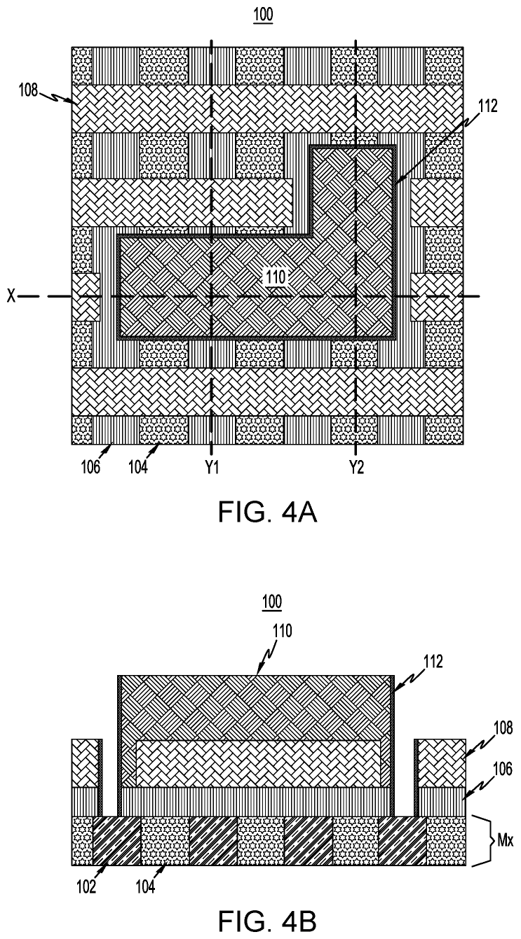

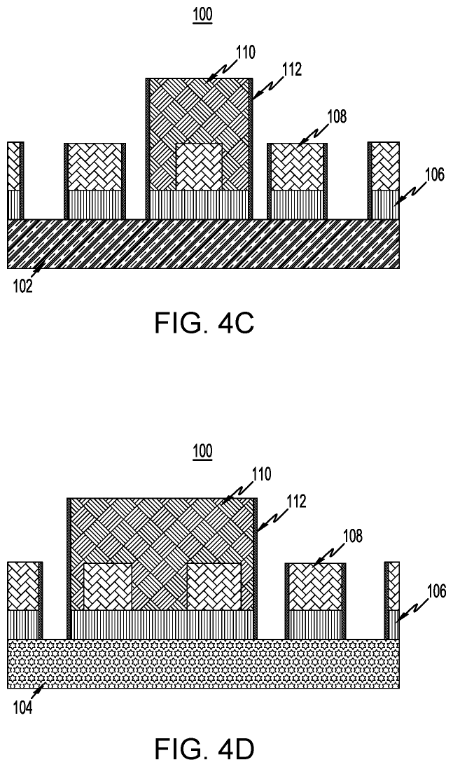

FIG. 4A shows a top-down view of a semiconductor structure 100, following formation of a masking layer and sidewall spacers for defining the area covered for the via metallization layer Vx and the second metallization layer Mx+1 on the via metallization layer Vx. FIG. 4B shows a first side cross-sectional view of semiconductor structure 100, taken along the X-X axis in the top-down view of FIG. 4A. FIG. 4C shows a second side cross-sectional view of semiconductor structure 100, taken along the Y1-Y1 axis in the top-down view of FIG. 4A. FIG. 4D shows a third side cross-sectional view of semiconductor structure 100, taken along the Y2-Y2 axis in the top-down view of FIG. 4A.

A mask layer 110 such as an organic planarization layer (OPL) or a spin-on-carbon (SOC) is first deposited on semiconductor structure 100 using any conventional deposition process such spin-on coating or any other suitable deposition process. The mask layer 110 is then patterned to cover selected areas of second metallization layer 108 and via metallization layer 106. The exposed portions of second metallization layer 108 and via metallization layer 106 is selectively etched until first metallization layer Mx is reached using any selective etching process such as ME.

Next, sidewall spacers 112 are formed on sidewalls of mask layer 110 and exposed sidewalls of second metallization layer 108 and via metallization layer 106. Suitable material for sidewall spacers 112 includes, for example, a nitride or an oxynitride such as, for example, Si₃N₄, SiBCN, SiNC, SiN, SiCO, SiO₂ and SiNOC. Sidewall spacers 112 can be formed using conventional deposition techniques such as by PVD, ALD, CVD, etc.

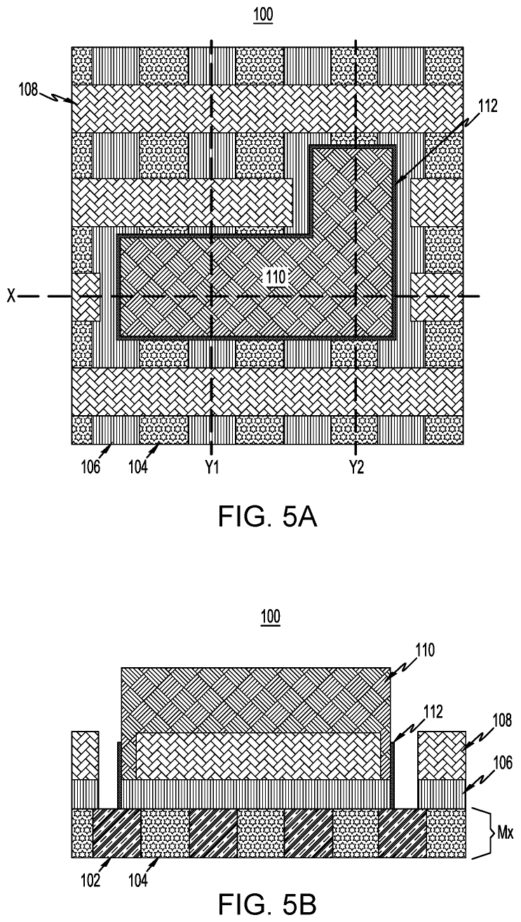

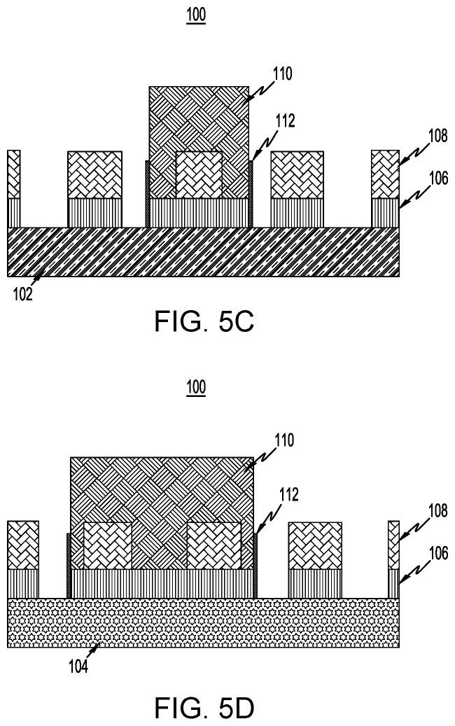

FIG. 5A shows a top-down view of a semiconductor structure 100, following removing selected portions of sidewall spacers 112 to expose the area of via metallization layer 106 to be removed in the next step. FIG. 5B shows a first side cross-sectional view of semiconductor structure 100, taken along the X-X axis in the top-down view of FIG. 5A. FIG. 5C shows a second side cross-sectional view of semiconductor structure 100, taken along the Y1-Y1 axis in the top-down view of FIG. 5A. FIG. 5D shows a third side cross-sectional view of semiconductor structure 100, taken along the Y2-Y2 axis in the top-down view of FIG. 5A.

Sidewall spacers 112 are selectively removed from the semiconductor structure 100 using any conventional etching process such as a wet or dry etch. The remaining sidewall spacers 112 cover the portions of via metallization layer 106 that are to be protected from a subsequent etching process.

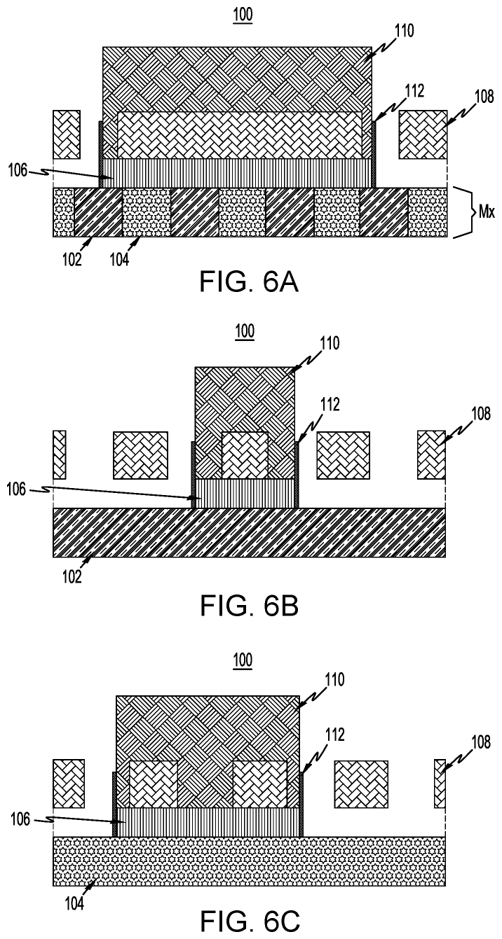

FIGS. 6A-6C illustrate a cross-sectional view of semiconductor structure 100 at a sixth-intermediate fabrication stage. During this stage, the exposed portions of via metallization layer 106 are selectively removed using any conventional etching process such as a wet or dry etch.

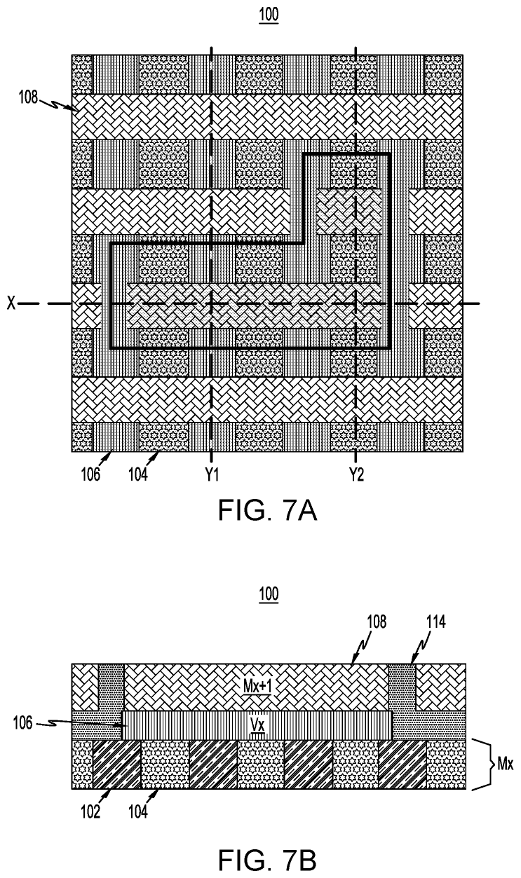

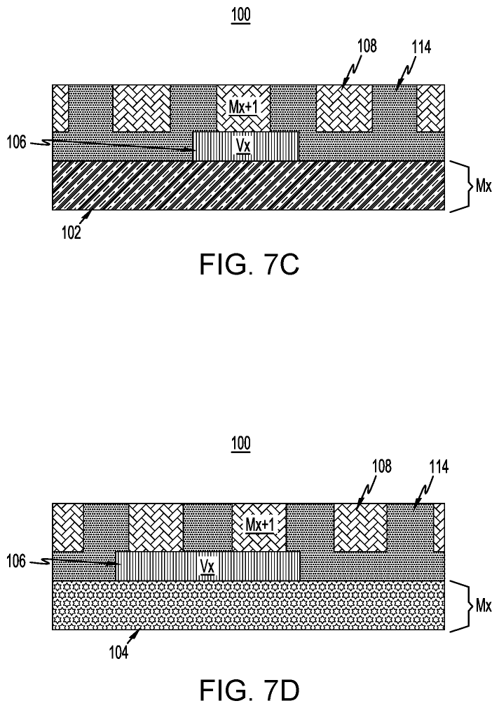

FIGS. 7A-7D illustrate a cross-sectional view of semiconductor structure 100 at a seventh-intermediate fabrication stage. During this stage, sidewall spacers 112 and mask layer 110 are removed and dielectric layer 114 is formed on the semiconductor structure 100. Sidewall spacers 112 and mask layer 110 are removed using any conventional etching process such as a wet or dry etch. Next, dielectric layer 114 is deposited in the remove portions of via metallization layer Vx and over the top surface of second metallization layer Mx+1. Dielectric layer 114 can be formed by a similar process and of a similar material as dielectric layer 102. Subsequently, a planarization process such as a standard planarization process (e.g., CMP process) can be carried out to planarize dielectric layer 114 so it is contiguous with the upper surface of metallization layer Mx+1.

FIG. 7B shows a first side cross-sectional view of semiconductor structure 100, taken along the X-X axis in the top-down view of FIG. 7A. In an illustrative embodiment, the via metallization layer Vx can have a width that is greater than a width of second metallization layer Mx+1 (in the X-X direction). In an illustrative embodiment, the via metallization layer Vx can have a width that is less than a width of second metallization layer Mx+1 (in the X-X direction).

FIG. 7C shows a second side cross-sectional view of semiconductor structure 100, taken along the Y1-Y1 axis in the top-down view of FIG. 7A. In an illustrative embodiment, the via metallization layer Vx can have a width that is greater than a width of second metallization layer Mx+1 (in the Y1-Y1 direction). In an illustrative embodiment, the via metallization layer Vx can have a width that is less than a width of second metallization layer Mx+1 (in the Y1-Y1 direction).

FIG. 7D shows a third side cross-sectional view of semiconductor structure 100, taken along the Y2-Y2 axis in the top-down view of FIG. 7A. In an illustrative embodiment, the via metallization layer Vx can have a width that is greater than a width of second metallization layer Mx+1 (in the Y2-Y2 direction). In an illustrative embodiment, the via metallization layer Vx can have a width that is less than a width of second metallization layer Mx+1 (in the Y2-Y2 direction).

FIGS. 7B-7D further show a via metallization layer Vx connecting the first metallization layer Mx to the second metallization layer Mx+1, wherein the via metallization layer Vx comprises a metal via having a first portion extending in a first direction (e.g., the X-X direction) and a second portion extending from the first portion in a second direction (e.g., the Y1-Y1 direction or the Y2-Y2 direction) different than the first direction.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An interconnect structure, comprising:
a first metallization layer;
a second metallization layer; and
a via metallization layer connecting the first metallization layer to the second metallization layer, wherein the via metallization layer comprises a metal via having a first portion extending in a first direction and a second portion extending from the first portion in a second direction different than the first direction.

2. The interconnect structure according to claim 1, wherein the first metallization layer comprises a plurality of metal lines disposed within a first dielectric layer.

3. The interconnect structure according to claim 2, wherein the metal via is disposed within a second dielectric layer.

4. The interconnect structure according to claim 3, wherein the second metallization layer is further disposed within the second dielectric layer.

5. The interconnect structure according to claim 1, wherein the second metallization layer comprises a plurality of metal lines.

6. The interconnect structure according to claim 5, wherein the metal via comprises a first conductive metal and the plurality of metal lines of the second metallization layer comprise a second conductive metal different than the first conductive metal.

7. The interconnect structure according to claim 6, wherein the first conductive metal is Co and the second conductive metal is Ru.

8. The interconnect structure according to claim 6, wherein the first conductive metal is Al and the second conductive metal is Ru.

9. An interconnect structure, comprising:
a first metallization layer;
a second metallization layer; and
a via metallization layer connecting the first metallization layer to the second metallization layer;
wherein the via metallization layer comprises a metal via having a first portion extending in a first direction and a second portion extending from the first portion in a second direction different than the first direction; and
wherein the first portion of the metal via has a first width and the second via portion of the metal via has a second width different than the first width.

10. The interconnect structure according to claim 9, wherein the first metallization layer comprises a plurality of metal lines disposed within a first dielectric layer.

11. The interconnect structure according to claim 10, wherein the metal via is disposed within a second dielectric layer.

12. The interconnect structure according to claim 11, wherein the second metallization layer is further disposed within the second dielectric layer.

13. The interconnect structure according to claim 9, wherein the second metallization layer comprises a plurality of metal lines.

14. The interconnect structure according to claim 13, wherein the metal via comprises a first conductive metal and the plurality of metal lines of the second metallization layer comprise a second conductive metal different than the first conductive metal.

15. The interconnect structure according to claim 14, wherein the first conductive metal is one of Co and Al and the second conductive metal is Ru.

16. The interconnect structure according to claim 9, wherein the first width is greater than the second width.

17. An integrated circuit, comprising:
one or more interconnect structures, wherein at least one of the one or more interconnect structures comprises:
a first metallization layer;
a second metallization layer; and
a via metallization layer connecting the first metallization layer to the second metallization layer, wherein the via metallization layer comprises a metal via having a first portion extending in a first direction and a second portion extending from the first portion in a second direction different than the first direction.

18. The integrated circuit according to claim 17, wherein the first metallization layer comprises a plurality of metal lines disposed within a first dielectric layer; the metal via is disposed within a second dielectric layer; and the second metallization layer is further disposed within the second dielectric layer.

19. The integrated circuit according to claim 17, wherein the second metallization layer comprises a plurality of metal lines.

20. The integrated circuit according to claim 19, wherein the metal via comprises a first conductive metal and the plurality of metal lines of the second metallization layer comprise a second conductive metal different than the first conductive metal.
